(19) United States
(12) Patent Application Publication
(10) Pub. No.: US 2024/0332229 A1
(43) Pub. Date: Oct. 3, 2024

(54) SEMICONDUCTOR DEVICE WITH DUAL DAMASCENE AND DUMMY PADS

(71) Applicant: Micron Technology, Inc., Boise, ID (US)

(72) Inventors: Bharat Bhushan, Taichung (TW); Tzu Ching Hung, Taichung (TW); Kyle K. Kirby, Eagle, ID (US); Julia VanWinkle, Boise, ID (US); Kyle B. Campbell, Boise, ID (US); Bret K. Street, Meridian, ID (US)

(21) Appl. No.: 18/619,071

(22) Filed: Mar. 27, 2024

Related U.S. Application Data
(60) Provisional application No. 63/456,747, filed on Apr. 3, 2023.

(51) Int. Cl. H01L 23/00; H01L 21/66

(52) U.S. Cl. CPC H01L 24/06; H01L 22/32; H01L 24/03; H01L 24/08; H01L 2224/06517; H01L 2224/08146

(57) ABSTRACT

A semiconductor device is provided. The semiconductor device can have a front side at which circuitry is disposed. The circuitry can include a pad and a plurality of lines. A first layer of dielectric material can be disposed at the front side at least partially over the pad and the plurality of lines. A second layer of dielectric material can be disposed at the front side at least partially over the first layer of dielectric material. A dual damascene pad can extend through the first layer of dielectric material and the second layer of dielectric material to the pad. A dummy pad can be disposed in the second layer of dielectric material above the plurality of lines and spaced from the dual damascene pad. In doing so, a reliable semiconductor device can be implemented.

### CROSS-REFERENCE TO RELATED APPLICATION(S)

The present application claims priority to U.S. Provisional Patent Application No. 63/456,747, filed Apr. 3, 2023, the disclosure of which is incorporated herein by reference in its entirety.

### TECHNICAL FIELD

The present disclosure generally relates to semiconductor device assemblies and more particularly relates to a semiconductor device with dual damascene and dummy pads.

### BACKGROUND

Microelectronic devices generally have a die (e.g., a chip) that includes integrated circuitry with a high density of very small components. Typically, dies include an array of bond pads electrically coupled with the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled with the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly.

FIG. 2 illustrates a simplified schematic cross-sectional view of a semiconductor device assembly in accordance with an embodiment of the present technology.

FIGS. 3-6 illustrate simplified schematic cross-sectional views of a series of steps for fabricating a semiconductor device assembly in accordance with an embodiment of the present technology.

FIG. 7 illustrates a simplified schematic cross-sectional view of a semiconductor device assembly in accordance with an embodiment of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

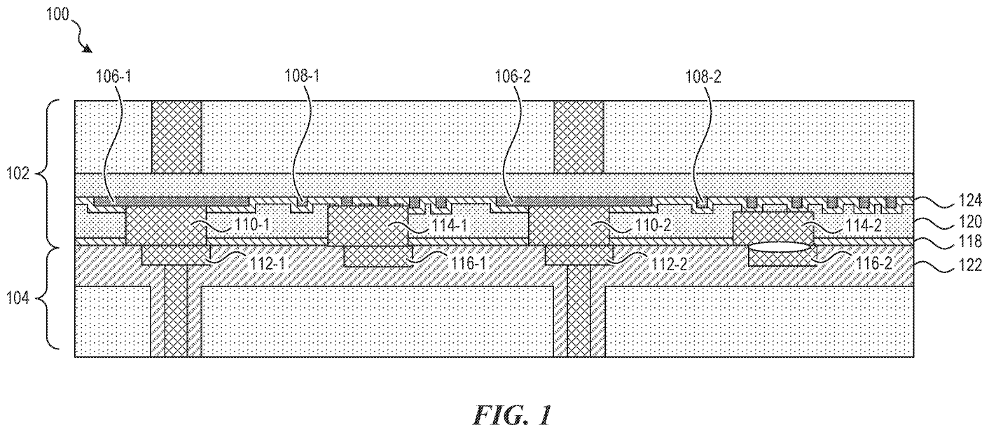

Semiconductor devices are integrated into many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, stacked semiconductor devices are implemented to increase the number of circuit elements on a semiconductor device without simultaneously increasing the device footprint. Implementing stacked semiconductor devices, however, may present additional design challenges, some of which are illustrated in FIG. 1.

FIG. 1 illustrates a simplified schematic cross-sectional view of a semiconductor device assembly 100. The semiconductor device assembly 100 includes a semiconductor die 102 coupled with a semiconductor die 104. The semiconductor die 102 includes circuitry (e.g., contact pads 106 and lines 108) that provide connectivity to internal circuitry of the semiconductor die 102. Contact pads 110 are implemented at the contact pads 106 and coupled with contact pads 112 at the semiconductor die 104 to implement interconnects that electrically couple the semiconductor dies. As illustrated, the semiconductor die 102 also includes dummy pads 114 exposed at a surface of the semiconductor die 102 and coupled with dummy pads 116 at the semiconductor die 104.

As used herein, “a dummy pad” can refer to a conductive pad that is not used to form an interconnect between two semiconductor dies and thus can be disconnected from connective circuitry at the semiconductor dies. Instead, a dummy pad can be implemented to improve the mechanical coupling between dies, to improve the thermal regulation of a semiconductor device assembly, or to increase the uniformity along an exposed coupling surface of a semiconductor die.

For example, the contact pads 110 can be arranged along the surface of the semiconductor die 102 differently based on a specific configuration. In some arrangements, the contact pads 110 can have non-uniform pitch across the semiconductor die 102. When chemical-mechanical planarization (CMP) is used to planarize the coupling surface of the semiconductor, large gaps or non-uniformities across the semiconductor dies can cause inconsistencies at the coupling surface that can impact the coupling between the semiconductor dies. For instance, as illustrated between dummy pad 114-2 and dummy pad 116-2, dishing can occur, thereby limiting the adhesion between the semiconductor dies or shorting the interconnects. As another example, erosion 118 can occur at dielectric material 120 (e.g., silicon oxide, silicon nitride, silicon carbide, silicon carbon nitride) or dielectric material 122 (e.g., silicon oxide, silicon nitride, silicon carbide, silicon carbon nitride) at the coupling surface of the semiconductor die 102 and the semiconductor die 104, respectively, which can decrease the adhesion between the semiconductor dies or cause conductive material to bleed into circuitry exposed through the erosion 118 and short the semiconductor device assembly 100.

In yet another aspect, the dummy pads 114 can short the semiconductor device assembly 100 through the circuitry at the semiconductor die 102. For example, dielectric material 124 can be disposed at least partially over the circuitry (e.g., contact pads 106 and lines 108). Openings can be created in the dielectric material 120 and conductive material may be deposited in the opening to implement the dummy pads 114. When creating the openings, the dielectric material 124 can be removed and the conductive material implementing the dummy pads 114 can directly contact the lines 108 (e.g., where the dielectric material is removed or through seams in the dielectric material 124), as illustrated by dummy pad 114-1 and lines 108-1, thereby shorting the semiconductor device assembly 100. In other cases, the dummy pads 114 and the lines 108 can form a capacitive coupling through the dielectric material 124, as illustrated by dummy pad 114-2 and lines 108-2, which can degrade the performance of the semiconductor device assembly 100. Moreover, dummy pads cannot be implemented at some locations, for example, within a short distance above a probe pad, given that these dummy pads can cause deformation when implemented too close to other circuitry (e.g., less than 1 micron away, less than 2 microns away, less than 3 microns away).

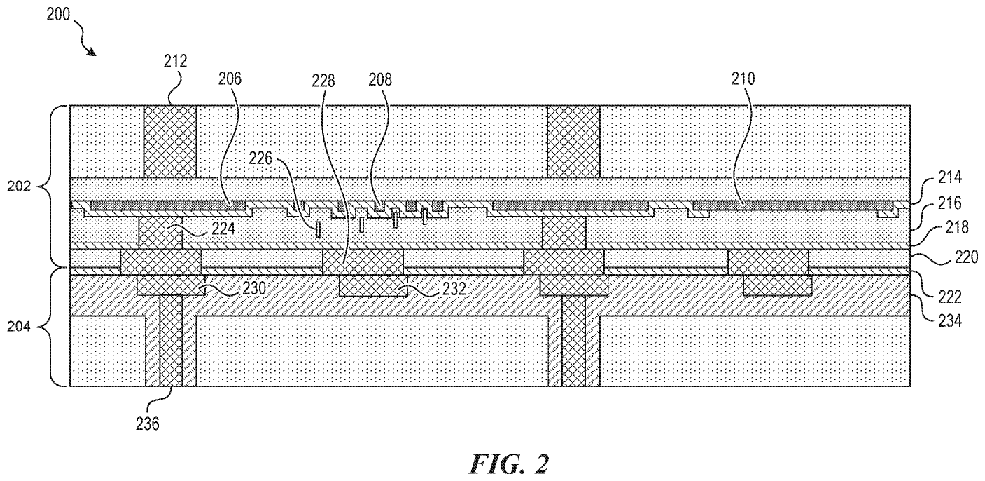

To address these drawbacks and others, the present technology discloses a semiconductor device with dual damascene and dummy pads. The semiconductor device can have a front side at which circuitry is disposed. The circuitry can include a pad and a plurality of lines. A first layer of dielectric material can be disposed at the front side at least partially over the pad and the plurality of lines. A second layer of dielectric material can be disposed at the front side at least partially over the first layer of dielectric material. The dual damascene pad can extend through the first layer of dielectric material and the second layer of dielectric material to the pad. The dummy pad can be disposed in the second layer of dielectric material above the plurality of lines to prevent electrical contact therewith. In doing so, a reliable semiconductor device can be implemented, an example of which is illustrated in FIG. 2.

FIG. 2 illustrates a simplified schematic cross-sectional view of a semiconductor device assembly 200 in accordance with an embodiment of the present technology. The semiconductor device assembly 200 includes a semiconductor die 202 coupled with a semiconductor die 204. The semiconductor die 202 includes routing circuitry (e.g., contact pads 206, lines 208, probe pad 210) at a front side that provides connectivity to internal circuitry of the semiconductor die 202 or additional semiconductor dies coupled with through-silicon vias (TSVs) 212 exposed at the back side. A layer of dielectric material 214 (e.g., silicon oxide, silicon nitride, silicon carbide, silicon carbon nitride) can be disposed at least partially over the contact pads 206, the lines 208, or the probe pad 210. A layer of dielectric material 216 (e.g., silicon oxide, silicon nitride, silicon carbide, silicon carbon nitride) can be disposed at least partially over the layer of dielectric material 214. A layer of dielectric material 218, a layer of dielectric material 220, and a layer of dielectric material 222 can be layered at the front side of the semiconductor die 202 over the layer of dielectric material 216.

In some cases, the layer of dielectric material 214 can include a thin layer (e.g., less than 0.1 microns, less than 0.2 microns, less than 0.5 microns) of silicon carbon nitride (e.g., deposited at a temperature greater than 350 degrees Celsius). The layer of dielectric material 214 can be disposed at the surface at which the contact pads 206, the lines 208, or the probe pad 210 is disposed. The layer of dielectric material 214 can extend over the sides of the contact pads 206 and partially over a coupling surface of the contact pads 206, leaving an exposed surface at which dual damascene pads 224 are coupled. The layer of dielectric material 214 can extend over and between the lines 208. The layer of dielectric material 214 can further extend over a portion of the probe pad 210 such that a portion of the probe pad 210 is exposed to enable testing of the semiconductor die 202.

The layer of dielectric material 216 can be disposed at least partially over the layer of dielectric material 214. In aspects, the layer of dielectric material 216 is a dielectric block, which can include, for example, silicon oxide (e.g., deposited at a temperature greater than 350 degrees Celsius). In aspects, deposition of the layer of dielectric material 216 can cause pinch off when deposited around the lines 208, causing airgaps 226 to form in the layer of dielectric material 216. The airgaps 226 can be located above the lines 208, laterally between adjacent pairs of the lines 208. The layer of dielectric material 216 can be deposited with a thickness sufficient to keep dummy pads 228 from contacting the circuitry (e.g., lines 208, probe pad 210) at the semiconductor die 202. For example, the layer of dielectric material 216 can be deposited with a thickness greater than 1 micron, greater than 2 microns, greater than 3 microns, greater than 5 microns, and so on.

The layer of dielectric material 218 can be disposed at least partially over the layer of dielectric material 216. In aspects, the layer of dielectric material 218 can include silicon carbon nitride (e.g., deposited at a temperature above 350 degrees Celsius). The layer of dielectric 218 can be a thin layer of dielectric material (e.g., less than 0.1 microns, less than 0.2 microns, less than 0.5 microns). The layer of dielectric material 220 can be disposed at least partially over the layer of dielectric material 218. The layer of dielectric material 220 can include a silicon block (e.g., of silicon oxide) with a thickness sufficient to implement an exposed portion of the dual damascene pads 224 or the dummy pads 228 (e.g., greater than 0.5 microns, greater than 1 micron, greater than 1.5 microns, greater than 2 microns). The layer of dielectric material 222 (e.g., a thin layer of silicon carbon nitride) can then be disposed at least partially over the layer of dielectric material 220 to provide a passivized coupling surface. The layer of dielectric material 222 can extend over a coupling surface of the semiconductor die 202 except at the dual damascene pads 224 and the dummy pads 228, thereby exposing a coupling surface of the dual damascene pads 224 and the dummy pads 228.

The dual damascene pads 224 can be implemented at the front side of the semiconductor die 202 and extending through the layers of dielectric material (e.g., layer of dielectric material 214, 216, 218, 220, 222) to the contact pads 206 (e.g., aluminum pads, copper pads). The dual damascene pads 224 can be implemented using a conductive material (e.g., copper, gold, silver). The dual damascene pads 224 can have an outer portion disposed in the layer of dielectric material 220 and an inner portion disposed in the layer of dielectric material 216. The outer portion can be implemented such that it extends to the layer of dielectric material 218. The outer portion can have a width greater than the inner portion. For example, the outer portion can have a width greater than 3 microns, greater than 4 microns, greater than 5 microns, and so on, and the inner portion can have a width less than 3 microns, less than 2 microns, and so on.

The dummy pads 228 can be implemented at the front side of the semiconductor die 202 laterally spaced from the dual damascene pads 224. The dummy pads 228 can be located at a same lateral location as and spaced above (e.g., by more than 1 micron, by more than 2 microns, by more than 3 microns, by more than 5 microns) the lines 208, the airgaps 226, or the probe pad 210. In this way, electrical contact with the lines 208 or the probe pad 210 can be prevented. Moreover, conductive material from the dummy pads 228 may not leak into the airgaps 226. The dummy pads 228 can extend through the layer of dielectric material 220 (e.g., and the layer of dielectric material 222) to the layer of dielectric material 218. In aspects, uniformity can be maintained across the semiconductor die 202 to control the effects of CMP, provide consistent thermal regulation, etc. In this way, the pitch of the dual damascene pads 224 and the dummy pads 228 (e.g., or the dummy pads 228 alone) can be consistent across the semiconductor die 202. For example, the dual damascene pads 224 and the dummy pads 228 can have a pitch less than 10 microns, less than 15 microns, less than 20 microns, and so on.

The dual damascene pads 224 and the dummy pads 228 can connect to contact pads 230 (e.g., copper pads) and dummy pads 232 (e.g., copper pads) at the semiconductor die 204, respectively. The contact pads 230 and the dummy pads 232 can be implemented within a layer of dielectric material 234 (e.g., silicon oxide, silicon nitride, silicon carbide, silicon carbon nitride) at a back side of the semiconductor die 204. The layer of dielectric material 234 can bond (e.g., fusion bond) with dielectric material at the semiconductor die 202 (e.g., the layer of dielectric material 222). The contact pads 230 and the dummy pads 232 can couple (e.g., metal-metal bond, hybrid bond) with the dual damascene pads 224 and the dummy pads 228, respectively. In doing so, the contact pads 230 and the dual damascene pads 224 can form interconnects that electrically couple the semiconductor die 202 and the semiconductor die 204, and the dummy pads 232 and the dummy pads 228 can bond to improve the coupling between the semiconductor dies and the thermal regulation of the semiconductor device assembly 200. Moreover, the contact pads 230 can connect to TSVs 236 to provide connectivity to a substrate (e.g., printed-circuit board (PCB), interposer, semiconductor die) coupled with the semiconductor die 204 at the TSVs 236.

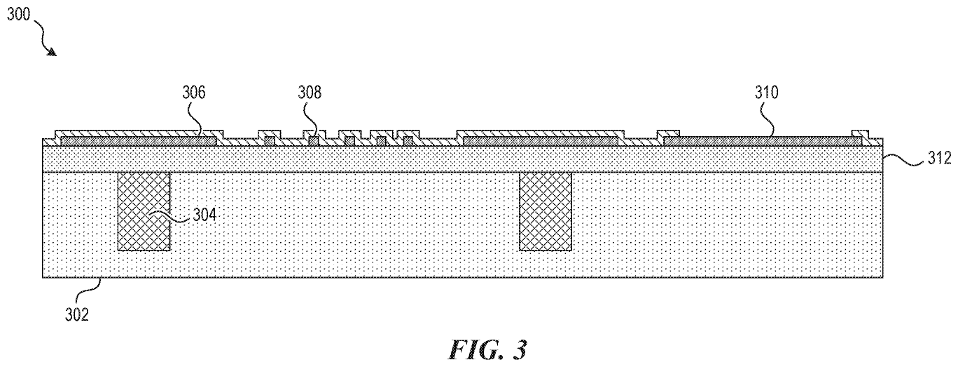

Various techniques can be used to fabricate a semiconductor device with a conductive pillar that includes a thermally conductive material. One example for fabricating such a semiconductor device assembly is illustrated in FIGS. 3-6. Specifically, FIG. 3 illustrates a simplified schematic cross-sectional view of a semiconductor device assembly 300. The semiconductor device assembly 300 includes a substrate 302 (e.g., organic substrate, semiconductor substrate), which can be a wafer-level, panel-level, or die-level substrate. In aspects, the substrate 302 is a silicon wafer. The semiconductor device assembly can include TSVs 304 that extend through the substrate 302. Circuitry can be disposed at the front side of the substrate 302 (e.g., coupled through routing circuitry to the TSVs 304). The circuitry can include contact pads 306, lines 308, or a probe pad 310.

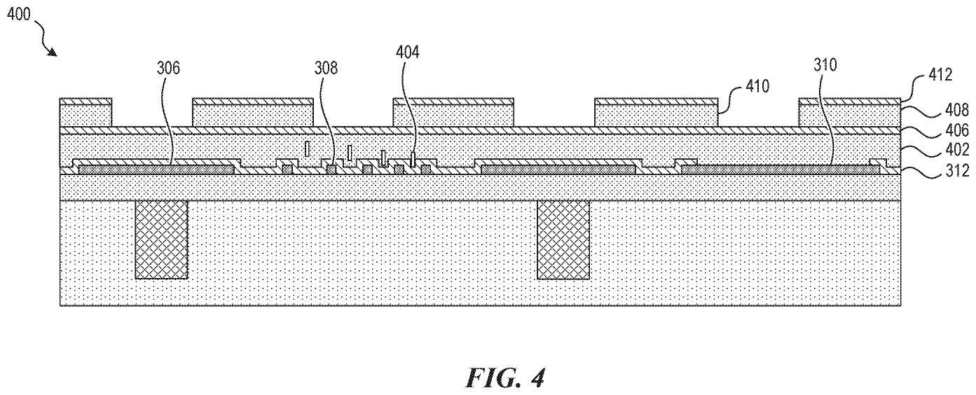

A layer of dielectric material 312 can be disposed over the contact pads 306, the lines 308, or the probe pad 310. The layer of dielectric material 312 can be deposited using any appropriate technique, for example, chemical vapor deposition (CVD) or physical vapor deposition (PVD). The layer of dielectric material 312 can be deposited within the gaps between the lines 308. In aspects, the layer of dielectric material 312 can be removed at some locations to expose the circuitry. For example, the layer of dielectric material 312 disposed on top of the probe pad 310 can be removed to expose a testing surface. A testing tool can be used to probe the testing surface of the probe pad 310 to test the circuitry. Once testing has completed, additional layers of dielectric material can be deposited at the front side, as illustrated in FIG. 4.

FIG. 4 illustrates a simplified schematic cross-sectional view of a semiconductor device assembly 400. A layer of dielectric material 402 (e.g., dielectric block) can be deposited over the layer of dielectric material 312. In some cases, after one or more of the layers of dielectric material are deposited, the dielectric material can be planarized (e.g., using CMP). As illustrated, the layer of dielectric material 402 is deposited over the testing surface of the probe pad 310. The layer of dielectric material 402 can have sufficient thickness to prevent electrical connection (e.g., physical contacting, conductive coupling) with the contact pads 306, the lines 308, or the probe pad 310 (e.g., greater than 1 micron, greater than 2 microns, greater than 3 microns, greater than 5 microns). In some cases, depositing the layer of dielectric material 402 can create airgaps 404 within the layer of dielectric material 402. For example, the airgaps 404 can form between the lines 308. The layer of dielectric material 402 can have a flat, continuous upper surface (without openings). A layer of dielectric material 406 can be disposed over the layer of dielectric material 402.

A layer of dielectric material 408 (e.g., dielectric block) can then be disposed over the layer of dielectric material 406. The layer of dielectric material 408 can have a thickness sufficient to implement contact pads (e.g., greater than 0.5 microns, greater than 1 micron, greater than 2 microns). The layer of dielectric material 408 can be deposited with a continuous upper surface, and openings 410 can be formed in the layer of dielectric material 408. Alternatively, the layer of dielectric material 408 can be selectively deposited at only portions of the layer of dielectric material 406, leaving the openings 410 void of dielectric material. A layer of dielectric material 412 can be deposited over the layer of dielectric material 408. The openings 410 can extend through the layer of dielectric material 412.

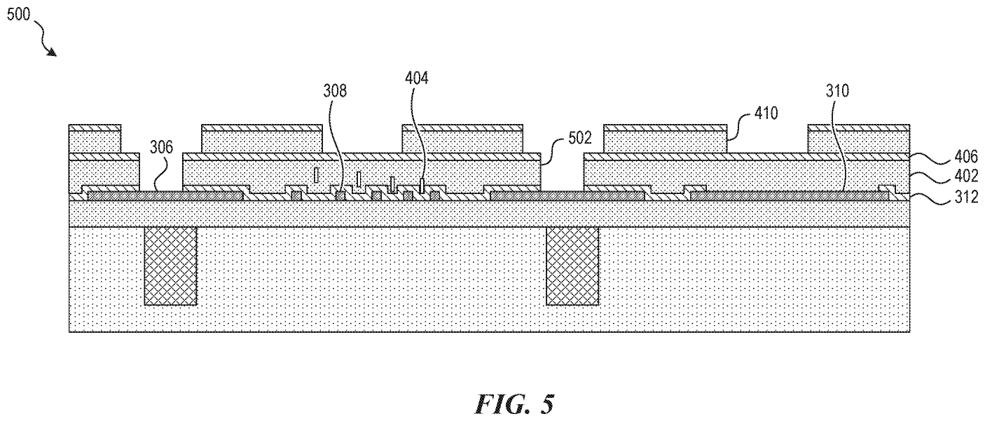

The openings 410 can be formed by removing the layer of dielectric material 408 and the layer of dielectric material 412 using any appropriate method (e.g., etching, drilling). The openings 410 can extend to the layer of dielectric material 406 with a width sufficient to implement contact pads. For example, the openings 410 can have a width greater than 2 microns, greater than 3 microns, greater than 5 microns, and so on. The openings 410 can be disposed at lateral locations that correspond to the circuitry. For example, the openings 410 can be formed above the contact pads 306, the lines 308, or the probe pad 310. In some cases, one or more of the openings 410 can be located above the airgaps 404. The openings 410 can be disposed uniformly across the surface of the semiconductor device assembly 400. Additional openings can then be formed at the openings 410, as illustrated in FIG. 5.

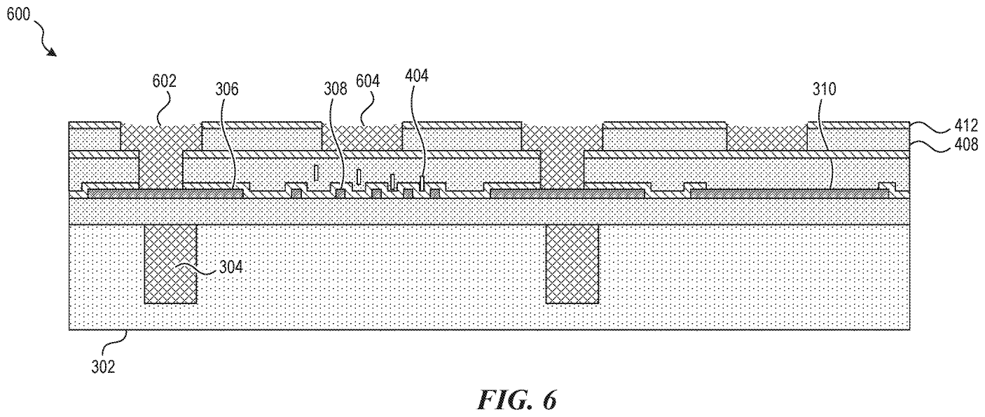

FIG. 5 illustrates a simplified schematic cross-sectional view of a semiconductor device assembly 500. Openings 502 can extend through the layer of dielectric material 312, the layer of dielectric material 402, and the layer of dielectric material 406. The openings 502 can be created within one or more of the openings 410. For example, the openings 502 can be created in the openings 410 that correspond to the contact pads 306 but not in the openings 410 that correspond to the lines 308 or the probe pad 310. The openings 502 can extend entirely through the layers of dielectric material to expose a surface of the contact pads 306. The openings 502 can have a width smaller than the width of the openings 410. For example, the openings 502 can have a width less than 1 micron, less than 2 microns, less than 3 microns, less than 5 microns, and so on. The openings 502 can be formed using any appropriate technique, for example, a technique the same as or different from the techniques used to create the openings 410. Conductive material can then be disposed in the openings 410 and the openings 502 to implement circuitry, as illustrated in FIG. 6.

FIG. 6 illustrates a simplified schematic cross-sectional view of a semiconductor device assembly 600 after conductive material has been disposed in the openings to implement dual damascene pads 602 and dummy pads 604. The conductive material can be disposed through any appropriate method (e.g., dispensing). The dual damascene pads 602 can extend to the contact pads 306 and have an exposed coupling surface. In this way, circuitry at the semiconductor device assembly 600 can be coupled with additional semiconductor dies through the dual damascene pads 602. The dummy pads 604 can be located above the lines 308 or the probe pad 310. The dummy pads 604 can be separated from the lines 308 or the probe pad 310 by a sufficient distance to prevent electrical coupling. In some cases, the dummy pads 604 can be located above and in a same lateral location as the airgaps 404. In this way, the conductive material will not bleed into the airgaps 404 and short the semiconductor device assembly 600.

Once the conductive material has been disposed in the openings, the semiconductor device assembly 600 can be planarized (e.g., using CMP) to create a planar coupling surface. The planarization can cause material to be removed from the layer of dielectric material 412. However, the presence of the dummy pads 604 can prevent excessive erosion of the layer of dielectric material, which can expose the layer of dielectric material 408 in some locations and impact bonding or electrical performance. Moreover, the planarization can cause dishing on the dual damascene pads 602 or the dummy pads 604. In aspects, the dummy pads 604 can help to control CMP dishing, thereby reducing the likelihood of over- or under-expanded interconnects. Additional semiconductor dies (e.g., or a substrate) can then be coupled with the semiconductor device assembly 600 at the dual damascene pads 602 and the dummy pads 604.

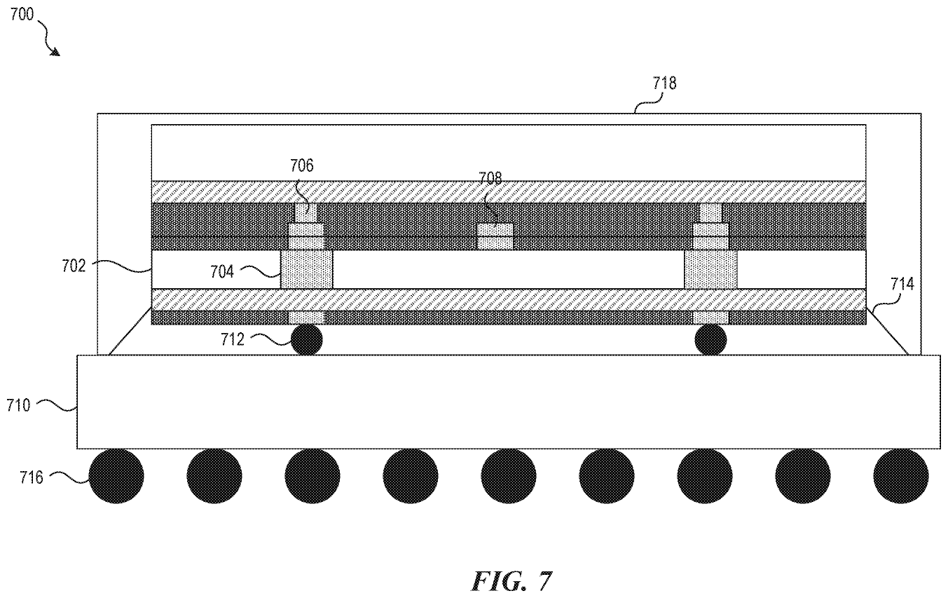

The substrate 302 can also be planarized (e.g., using CMP) to expose the TSVs 304. For example, material can be removed from the back side of the substrate 302 until the TSVs 304 are exposed. A layer of dielectric material can be disposed at the back side of the substrate 302, and contact pads can be implemented within the dielectric material. The contact pads can be disposed at the exposed portion of the TSVs 304. In this way, additional semiconductor dies (e.g., or a substrate) can be coupled with the semiconductor device assembly 600 at the contact pads. In doing so, a packaged semiconductor device can be assembled, an example of which is illustrated in FIG. 7.

FIG. 7 illustrates a simplified schematic cross-sectional view of a semiconductor device assembly 700 in accordance with an embodiment of the present technology. Semiconductor dies 702 can be coupled in a front-to-front arrangement, a front-to-back arrangement, or a back-to-back arrangement. One or more of the semiconductor dies 702 can include TSVs 704 to couple contact pads at a back side with a metallization layer (e.g., with traces, lines, vias, or other connection structures) at the front side. The semiconductor dies 702 can be electrically coupled through interconnects 706, for example, formed from dual damascene pads. The semiconductor dies 702 can also be coupled through dummy pads 708.

The semiconductor dies 702 may be coupled with a package-level substrate 710 (e.g., PCB, interposer, another semiconductor die). Connective structures 712 (e.g., solder balls, solder bumps, conductive pillars) can be disposed between contact pads at a lower side of a bottom semiconductor die of the semiconductor dies 702 and contact pads (not shown) at an upper side of the package-level substrate 710 to implement interconnects that electrically couple the semiconductor dies 702 and the package-level substrate 710. An underfill material 714 (e.g., capillary underfill) can be provided between a bottom die of the semiconductor dies 702 and the package-level substrate 710 to provide electrical insulation to the connective structures 712 and structurally support the semiconductor device assembly 700. The package-level substrate 710 can include internal routing circuitry (e.g., traces, lines, vias, and other connection structures) that connects the contact pads at the upper side to contact pads at the lower side. Connective structures 716 may be disposed at the contact pads at the lower side to provide external connectivity to other devices (e.g., on a motherboard). The semiconductor device assembly 700 can further include an encapsulant material 718 (e.g., mold resin compound or the like) that at least partially encapsulates the stack of semiconductor dies 702 and the package-level substrate 710 to prevent electrical contact therewith or provide mechanical strength to the semiconductor device assembly 700.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In aspects, the semiconductor devices can be high-bandwidth memory (HBM) devices having one or more memory dies assembled onto a logic die (e.g., memory controller). In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.) or a mix of logic and memory dies (e.g., a memory controller die and a memory die controlled thereby). For example, an HBM device can include a logic die having 8, 12, 16, 20, 24 or any other number of memory dies assembled thereon.

### Example Systems

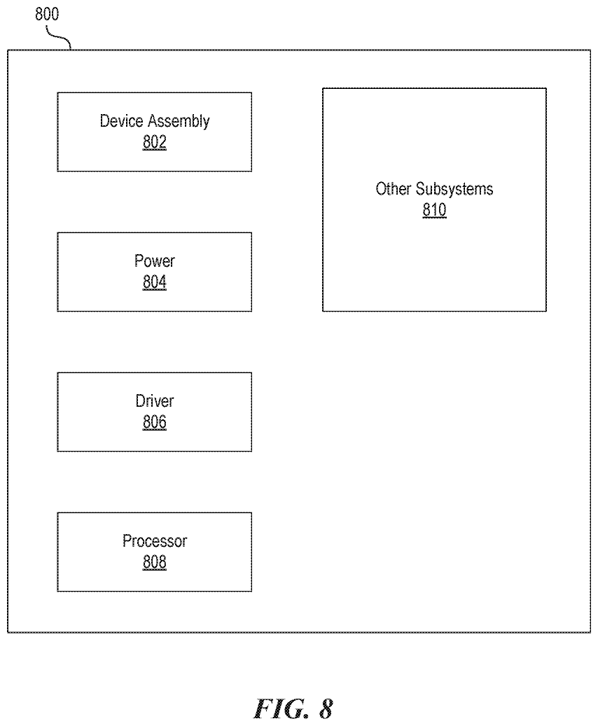

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances, and other products. Components of the system 800 can be housed in a single unit or distributed over multiple, interconnected units (e.g., through a communications network). The components of the system 800 can also include remote devices and any of a wide variety of computer-readable media.

This disclosure now turns to methods for fabricating semiconductor device assemblies in accordance with one or more embodiments of the present technology. Although illustrated in a particular configuration, operations within any of the methods may be omitted, repeated, or reorganized. Moreover, any of the methods may include additional operations, for example, those detailed in one or more other methods described herein.

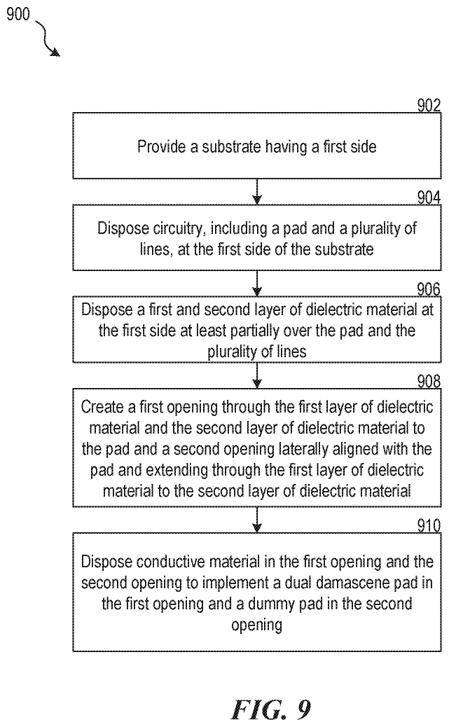

FIG. 9 illustrates a method 900 for fabricating a semiconductor device assembly. At 902, a substrate having a first side is provided. At 904, circuitry, including a pad and a plurality of lines, is disposed at the first side of the substrate. At 906, a first layer and a second layer of dielectric material are disposed. The first layer of dielectric material is disposed at the first side at least partially over the pad and the plurality of lines. The second layer of dielectric material is disposed at the first side at least partially over the first layer of dielectric material. At 908, a first opening and a second opening are created. The first opening extends through the first layer of dielectric material and the second layer of dielectric material to the pad. The second opening is laterally aligned with the plurality of lines and extends through the first layer of dielectric material to the second layer of dielectric material. At 910, conductive material is disposed in the first opening and the second opening to implement a dual damascene pad in the first opening and a dummy pad in the second opening.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using CVD, PVD, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, can be formed on a semiconductor substrate or die, such as silicon, germanium, silicon-germanium alloy, gallium arsenide, gallium nitride, etc. In some cases, the substrate is a semiconductor wafer. In other cases, the substrate can be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, can be controlled through doping using various chemical species including, but not limited to, phosphorous, boron, or arsenic. Doping can be performed during the initial formation or growth of the substrate, by ion-implantation, or by any other doping means.

The functions described herein can be implemented in hardware, software executed by a processor, firmware, or any combination thereof. Other examples and implementations are within the scope of the disclosure and appended claims. Features implementing functions can also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications can be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device comprising:
a front side at which circuitry is disposed, the circuitry including a pad and a plurality of lines;
a first layer of dielectric material disposed at the front side at least partially over the pad and the plurality of lines;
a second layer of dielectric material disposed at the front side at least partially over the first layer of dielectric material;
a dual damascene pad extending through the first layer of dielectric material and the second layer of dielectric material to the pad; and
a dummy pad disposed in the second layer of dielectric material above the plurality of lines and spaced from the dual damascene pad, the dummy pad electrically isolated from the circuitry disposed at the front side.

2. The semiconductor device of claim 1, further comprising a third layer of dielectric material disposed between the first layer of dielectric material and the second layer of dielectric material.

3. The semiconductor device of claim 2, wherein:
the first layer of dielectric material comprises a first dielectric material;
the second layer of dielectric material comprises a second dielectric material;
the third layer of dielectric material comprises a third dielectric material; and
the third dielectric material is different from the first dielectric material and the second dielectric material.

4. The semiconductor device of claim 3, wherein:
the first dielectric material or the second dielectric material comprises silicon oxide; and
the third dielectric material comprises silicon carbon nitride.

5. The semiconductor device of claim 1, further comprising:
an additional dual damascene pad; and
an additional dummy pad,
wherein the dual damascene pad, the dummy pad, the additional dual damascene pad, and the additional dummy pad are arranged with a same pitch.

6. The semiconductor device of claim 1, wherein a first portion of the dual damascene pad extending through the first layer of dielectric material has a width greater than three microns and a second portion of the dual damascene pad extending through the second layer of dielectric material has a width less than 3 microns.

7. The semiconductor device of claim 1, further comprising a third layer of dielectric material disposed at least partially between the circuitry and the first layer of dielectric material.

8. The semiconductor device of claim 1, further comprising:
a probe pad disposed at the front side; and
an additional dummy pad disposed in the second layer of dielectric material above the probe pad and spaced from the dual damascene pad and the dummy pad,
wherein the first layer of dielectric material is disposed at the front side at least partially over the probe pad.

9. A semiconductor device comprising:
a front side at which circuitry is disposed, the circuitry including a pad and a plurality of lines;
a first layer of dielectric material disposed at the front side at least partially over the pad and the plurality of lines, the first layer of dielectric material including airgaps located above and corresponding to the plurality of lines;
a second layer of dielectric material disposed at the front side at least partially over the first layer of dielectric material;
a dual damascene pad extending through the first layer of dielectric material and the second layer of dielectric material to the pad; and
a dummy pad disposed in the second layer of dielectric material above the airgaps.

10. The semiconductor device of claim 9, further comprising a third layer of dielectric material disposed between the first layer of dielectric material and the second layer of dielectric material.

11. The semiconductor device of claim 9, further comprising:
an additional dual damascene pad; and
an additional dummy pad,
wherein the dual damascene pad, the dummy pad, the additional dual damascene pad, and the additional dummy pad are arranged with a same pitch.

12. The semiconductor device of claim 9, wherein the first layer of dielectric material is thicker than 2 microns.

13. The semiconductor device of claim 9, further comprising a third layer of dielectric material disposed at least partially between the circuitry and the first layer of dielectric material.

14. The semiconductor device of claim 9, wherein airgaps are located between adjacent pairs of the plurality of lines.

15. The semiconductor device of claim 9, further comprising:
a probe pad disposed at the front side; and
an additional dummy pad disposed in the second layer of dielectric material above the probe pad and spaced from the dual damascene pad and the dummy pad,
wherein the first layer of dielectric material is disposed at the front side at least partially over the probe pad.

16. A method of fabricating a semiconductor device comprising:
providing a substrate having a first side;
disposing circuitry at the first side of the substrate, the circuitry including a pad and a plurality of lines;
disposing a first layer of dielectric material at the first side at least partially over the pad and the plurality of lines;
disposing a second layer of dielectric material at the first side at least partially over the first layer of dielectric material;
creating a first opening extending through the first layer of dielectric material and the second layer of dielectric material to the pad;
creating a second opening extending through the first layer of dielectric material to the second layer of dielectric material and laterally aligned with the plurality of lines; and
disposing conductive material in the first opening and the second opening to implement a dual damascene pad in the first opening and a dummy pad in the second opening.

17. The method of claim 16, further comprising disposing a third layer of dielectric material at the front side at least partially over the first layer of dielectric material, wherein the second layer of dielectric material is disposed at least partially over the third layer of dielectric material.

18. The method of claim 16, further comprising disposing a third layer of dielectric material at the front side at least partially over the circuitry, wherein the first layer of dielectric material is disposed at least partially over the third layer of dielectric material.

19. The method of claim 16, wherein creating the first opening comprises:
creating a third opening extending through the first layer of dielectric material to the second layer of dielectric material; and
creating a fourth opening at the third opening and extending through the second layer of dielectric material to the pad,
wherein the third opening has a greater width than the fourth opening.

20. The method of claim 16, wherein disposing the first layer of dielectric material causes airgaps to form in the first layer of dielectric material above and corresponding to the plurality of lines.
